(19) United States
(12) Patent Application Publication
(10) Pub. No.: US 2026/0052914 A1
(43) Pub. Date: Feb. 19, 2026

(54) PLASMA TREATMENT FOR DEPOSITION OF METALS

(71) Applicant: Tokyo Electron Limited, Tokyo (JP)

(72) Inventor: Yuji Otsuki, Albany, NY (US)

(21) Appl. No.: 18/807,873

(22) Filed: Aug. 16, 2024

(51) Int. Cl. H01L 21/02; H01J 37/32; H01L 21/285; H01L 21/768

(52) U.S. Cl. CPC H01L 21/02697; H01J 37/32091; H01J 37/32862; H01L 21/28506; H01L 21/76814; H01J 2237/3321

(57) ABSTRACT

In one example, a method for depositing ruthenium includes forming an opening in a dielectric layer disposed over a substrate, exposing the substrate including the opening to a first plasma in a plasma processing chamber including nitrogen and hydrogen, and exposing the substrate including the opening to a second plasma in the plasma processing chamber. The second plasma is hydrogen free. The method includes depositing ruthenium into the opening after exposing the substrate to the second p

[symbol]

### TECHNICAL FIELD

The present invention relates generally to semiconductor manufacturing, and, in particular embodiments, to plasma treatment for deposition of metals.

### BACKGROUND

In semiconductor manufacturing, particularly in advanced logic technologies, the ongoing pursuit of improved performance and miniaturization has led to exploration of alternative materials for conductive materials. As transistor dimensions continue to shrink, traditional copper interconnects face increasing challenges related to resistivity and electromigration. These limitations have prompted the industry to investigate novel materials that can maintain or enhance conductivity while addressing the obstacles posed by copper at smaller scales.

Ruthenium has emerged as a promising candidate for replacing copper in certain semiconductor applications. Its properties, including high electrical conductivity, enhanced resistance to electromigration, and potential for ultra-thin film deposition, make it an attractive option for advanced logic technologies. The integration of ruthenium into semiconductor manufacturing processes represents a significant shift in manufacturing, requiring significant development.

The deposition of ruthenium films presents several areas that have to be addressed for successful implementation in semiconductor manufacturing. One significant issue is achieving uniform and conformal deposition, especially in high-aspect-ratio structures common in advanced logic devices. Traditional deposition methods often struggle to produce consistent ruthenium layers in deep trenches and vias. Additionally, the strong tendency of ruthenium to form islands during initial growth stages can lead to discontinuous films, impacting electrical performance and reliability. Controlling film morphology and managing surface roughness are also concerns, as these factors directly influence the electrical properties and subsequent integration steps. Furthermore, the relatively high processing temperatures often required for ruthenium deposition can pose compatibility issues with other materials and thermal budget constraints in advanced semiconductor processes.

### SUMMARY

A method for depositing ruthenium includes forming an opening in a dielectric layer disposed over a substrate, exposing the substrate including the opening to a first plasma in a plasma processing chamber including nitrogen and hydrogen, and exposing the substrate including the opening to a second plasma in the plasma processing chamber. The second plasma is hydrogen free. The method includes depositing ruthenium into the opening after exposing the substrate to the second plasma.

A method for depositing ruthenium includes forming an opening in a dielectric layer disposed over a substrate, exposing the substrate including the opening to a first plasma in a plasma processing chamber including nitrogen and hydrogen, flowing an inert gas into the plasma processing chamber, generating a second plasma from the inert gas, and exposing the substrate including the opening to the second plasma, where the second plasma is hydrogen free. The method includes using a thermal chemical vapor deposition process, depositing ruthenium into the opening after exposing the substrate to the second plasma.

A method for depositing ruthenium includes forming an opening in a dielectric layer disposed over a substrate, the opening including sidewalls and a bottom surface. The method includes using a first plasma process, adsorbing nitrogen and hydrogen atoms to the bottom surface and sidewalls. The method includes using a second plasma process, selectively removing hydrogen atoms from upper portions of the sidewalls, and depositing ruthenium into the opening after the second plasma process.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A-1F illustrate cross-sectional views of a semiconductor device during various stages of fabrication of a contact in accordance with embodiments of the present application, wherein FIG. 1A illustrates an opening formed in a metallization layer, wherein FIG. 1B illustrates the opening after being subjected to a nitrogen and hydrogen containing first plasma, and FIG. 1C illustrates the opening after being subjected to a second plasma containing an inert gas but no hydrogen, wherein FIGS. 1D and 1E illustrate the gradual filling of the opening with a conductive fill material, wherein FIG. 1F illustrates after a planarization process so as to form the contact;

FIGS. 2A-2B illustrate cross-sectional views of a semiconductor device during various stages of fabrication in accordance with an embodiment, wherein FIG. 2A illustrates the device after the conductive fill process, and FIG. 2B illustrates the device after the planarization;

FIGS. 3A-3F illustrate flow charts depicting a method for depositing a conductive material, such as ruthenium, in an opening formed in an insulating layer during fabrication of a semiconductor device;

FIG. 4 illustrates a cross-sectional view of a semiconductor device formed using embodiments described above; and

FIG. 5 illustrates representative deposition rate of ruthenium after ammonia and nitrogen surface plasma pretreatments.

### DETAILED DESCRIPTION OF ILLUSTRATIVE EMBODIMENTS

Referring now to the drawings, wherein like reference numbers designate like or similar elements throughout the various views, illustrative embodiments are shown and described. The figures are not necessarily drawn to scale, and in some instances, the drawings have been simplified for illustrative purposes. One of ordinary skill in the art will appreciate the many possible applications and variations of embodiments based on this disclosure.

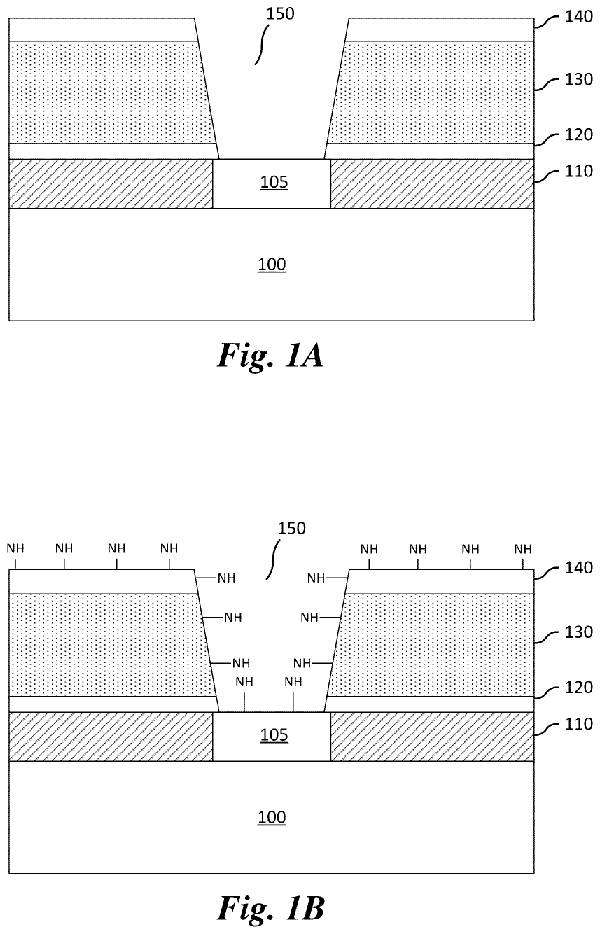

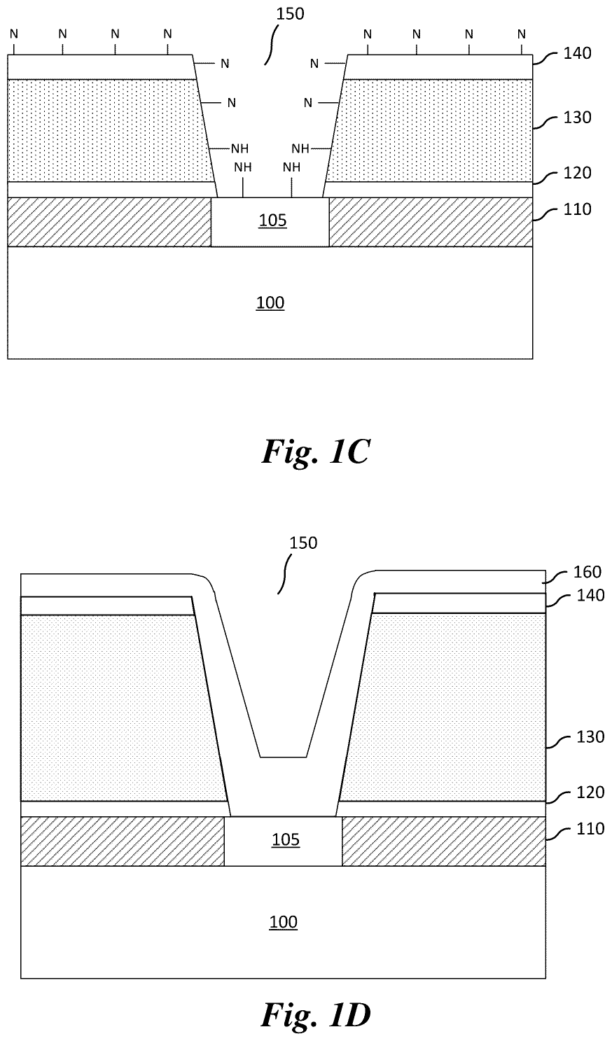

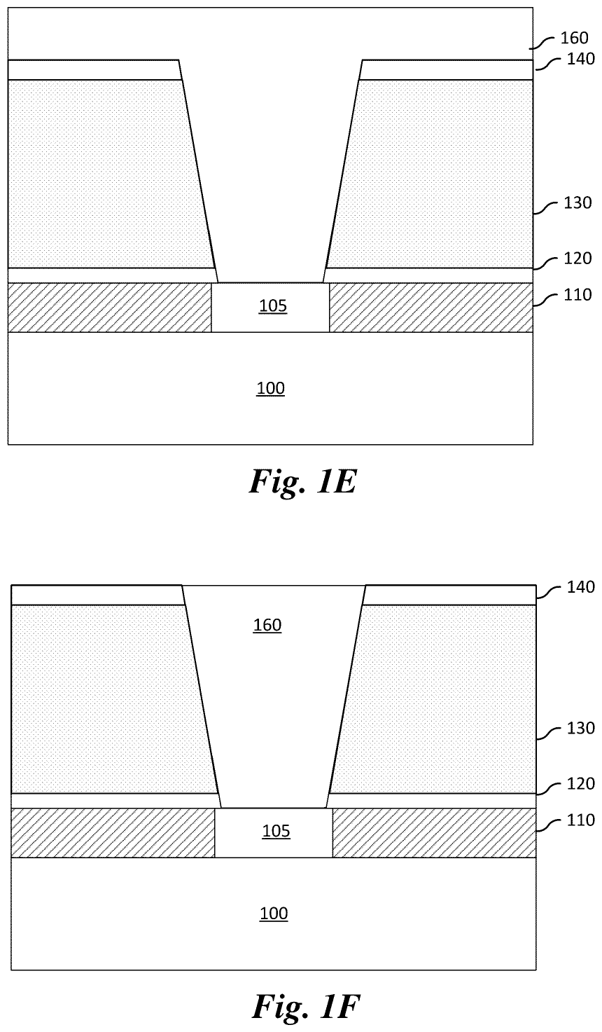

FIG. 1A-1F illustrate cross-sectional views of a semiconductor device during various stages of fabrication of a contact in accordance with embodiments of the present application, wherein FIG. 1A illustrates an opening formed in a metallization layer, wherein FIG. 1B illustrates the opening after being subjected to a nitrogen and hydrogen containing first plasma, and FIG. 1C illustrates the opening after being subjected to a second plasma containing an inert gas but no hydrogen, wherein FIGS. 1D and 1E illustrate the gradual filling of the opening with a conductive fill material, wherein FIG. 1F illustrates after a planarization process so as to form the contact.

FIG. 1A illustrates a cross-sectional view of a semiconductor device at an initial stage of fabrication in accordance with an embodiment of the present disclosure. The semiconductor device includes a substrate 100, which may be a semiconductor wafer. The substrate 100 may be composed of various materials suitable for semiconductor device fabrication. These materials include silicon (Si), silicon-on-insulator (SOI), silicon carbide (SiC), and compound semiconductors such as gallium arsenide (GaAs) and indium phosphide (InP). The substrate 100 may include various active device regions and isolation regions already formed at this stage of processing.

A first insulating layer 110 is disposed over the substrate 100. The first insulating layer 110 may comprise isolation/dielectric region in which a conductive region 105 is formed. The conductive region 105 may be a contact region of a transistor such as a source contact, drain contact, gate contact, or an underlying metal line in various embodiments.

A stack comprising a first etch stop liner 120, a second insulating layer 130, and a second etch stop liner 140 is deposited over the first insulating layer 110. The first etch stop liner 120 may comprise a nitride in one embodiment. The second etch stop liner 140 may be an oxide, or nitride in one or more embodiments.

The second insulating layer 130 may comprise more than one material layer in various embodiments. The second insulating layer 130 in one or more embodiments comprises a low-k dielectric material to reduce parasitic capacitance and improve the overall performance of the semiconductor device. Suitable low-k dielectric materials include organosilicate glass (OSG), fluorinated silicate glass (FSG), carbon-doped oxide (CDO), porous silicon dioxide, spin-on organic polymers such as SiLK™, hydrogen silsesquioxane (HSQ), and methylsilsesquioxane (MSQ).

The second insulating layer 130 may be deposited using various techniques, depending on the specific material and desired properties. Common deposition methods include Chemical Vapor Deposition (CVD), Plasma-Enhanced Chemical Vapor Deposition (PECVD), spin-on deposition, and Atomic Layer Deposition (ALD). For instance, if the second insulating layer 130 is an organosilicate glass, it may be deposited using PECVD with precursors such as trimethylsilane and oxygen.

The thickness of the second insulating layer 130 may vary depending on the technology node being used. Typically, for advanced semiconductor processes, the thickness of the second insulating layer 130 may range from about 20 nanometers to about 500 nanometers. In some embodiments, the thickness may be between 50 nanometers and 100 nanometers.

An opening 150 is formed in the first etch stop liner 120, the second insulating layer 130, and the second etch stop liner, exposing a portion of an underlying conductive region 105. The formation of the opening 150 in the second insulating layer 130 represents the first step in a process for depositing a conductive fill material within the structure.

The formation of the opening 150 may involve several steps, beginning with the deposition of a mask layer on top of the second insulating layer 130. This mask layer can be composed of materials such as amorphous carbon, antireflection layers, silicon dioxide, silicon nitride, or silicon oxynitride. A photoresist layer is then applied over the hard mask layer and patterned using lithography techniques. This involves exposing the photoresist to light through a photomask containing the desired pattern, followed by development to remove either the exposed or unexposed portions of the photoresist, depending on whether positive or negative photoresist is used.

The mask layer is then etched using the patterned photoresist as a mask. This can be done using techniques such as reactive ion etching (RIE) or plasma etching. After the mask layer is patterned, the remaining photoresist is removed, typically using a plasma ashing process or wet chemical stripping. The stack comprising the second etch stop liner 140, the second insulating layer 130, and the first etch stop liner 120 is then etched using the patterned hard mask to define the opening 150.

This etching process is typically anisotropic to create substantially vertical sidewalls and can be performed using RIE or other directional etching techniques. Finally, the mask layer is removed after the opening 150 is formed. This can be done using selective etching processes (e.g., wet etching) that remove the hard mask material without significantly affecting the second etch stop liner 140 or the exposed conductive region 105.

The opening 150 thus formed comprises sidewalls and a bottom surface. Depending on the specific application, the opening 150 may be configured as a contact hole to expose the underlying conductive region 105 or as a trench for a metal line. In some implementations, the opening 150 may comprise both a contact hole and a trench for a dual damascene structure (not as illustrated).

In some embodiments, the opening 150 has a high aspect ratio, which is defined as the ratio of the depth of the opening to its width. In advanced semiconductor processes, the aspect ratio of the opening 150 may be quite high, typically ranging from 10:1 to 40:1. For example, an opening with a depth of 400 nanometers and a width of 20 nanometers would have an aspect ratio of 20:1. These high aspect ratios present significant challenges during the filling of the opening with a conductive metal such as ruthenium without voids or defects.

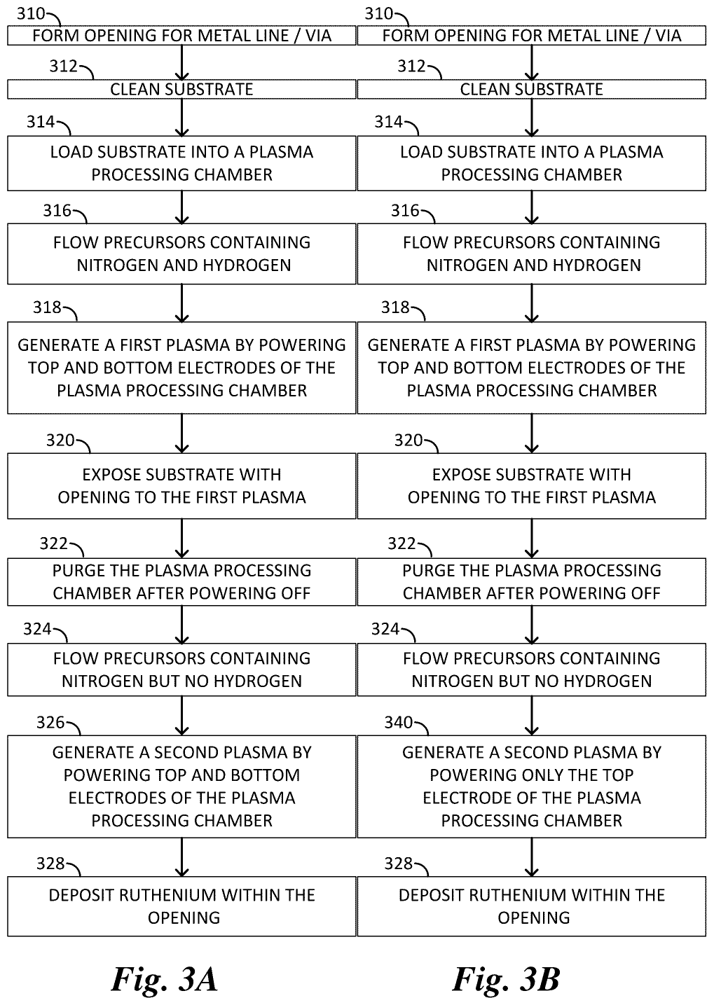

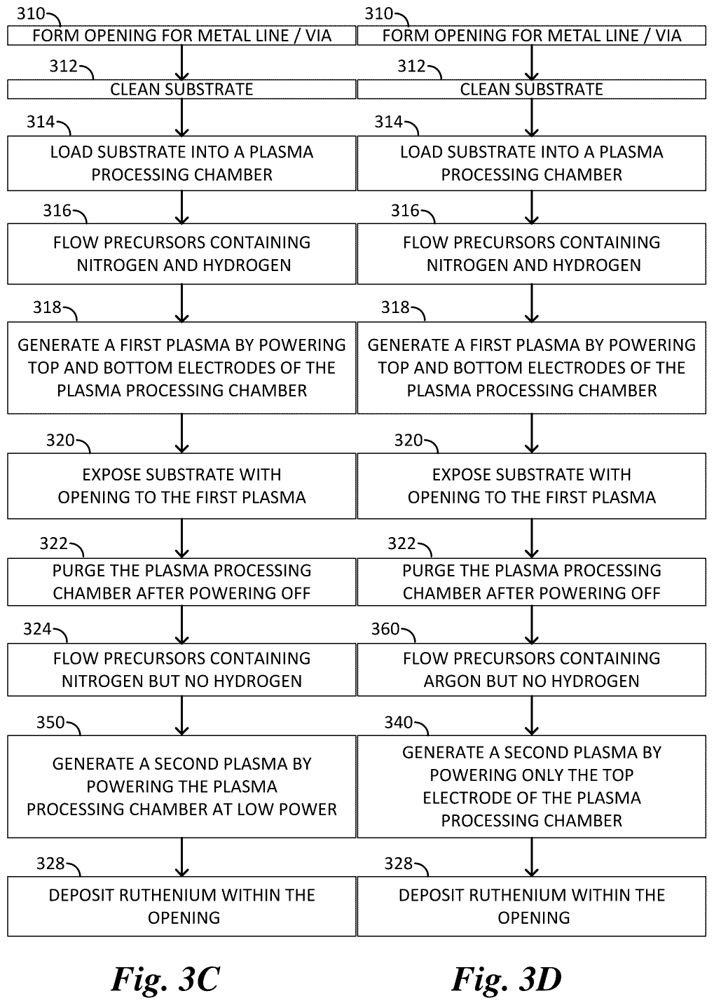

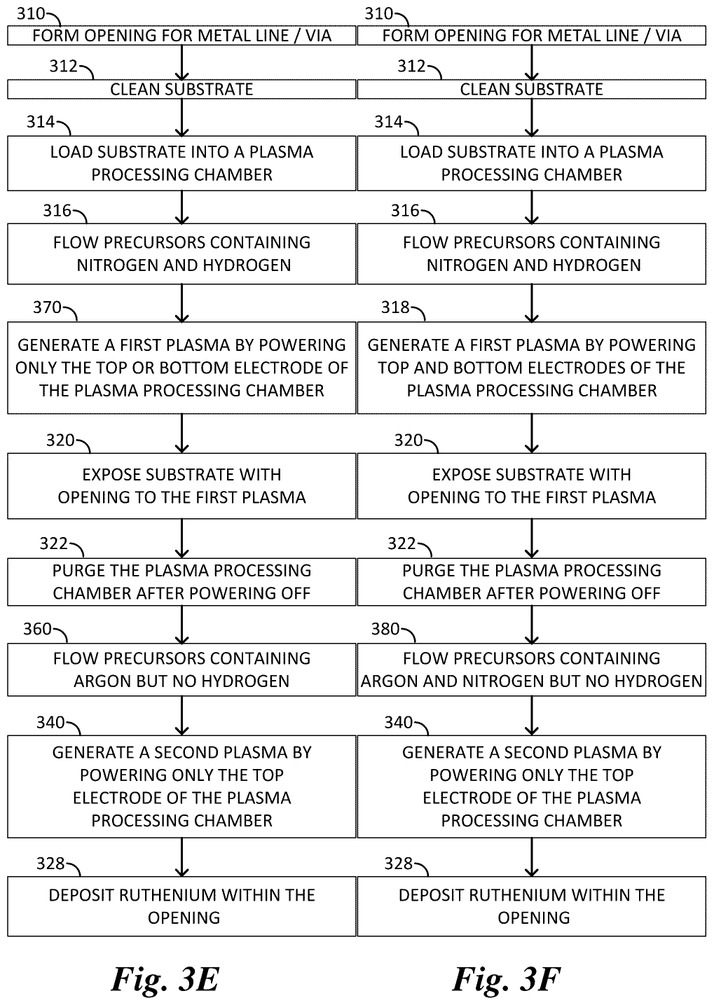

After the formation of the opening 150, and before any subsequent treatments, a cleaning step may be performed on the substrate. This cleaning step, as also illustrated in the flow charts of FIGS. 3A-3F, removes any residues or contaminants that may have been left behind from the etching process used to form the opening 150. The cleaning step helps to ensure a pristine surface for the subsequent plasma treatments and metal deposition. The cleaning may be a wet process or a plasma process in various embodiments.

This cleaning step may modify the surface chemistry of the exposed surfaces within the opening 150. Specifically, the cleaning process may remove some of the Si—H bonds that may be present on the surface and replace them with Si—O bonds. This transformation may make it easier to replace Si—O bonds in subsequent processing steps compared to Si—H bonds.

The replacement of Si—H bonds with Si—O bonds may be achieved through various cleaning methods. One common approach is to use a wet chemical cleaning process involving solutions that can oxidize the surface. Alternatively, a plasma-based cleaning process using oxygen-containing species may be employed. This surface modification enhances the effectiveness of the subsequent plasma treatments and metal deposition processes. By creating a surface termination that is more readily manipulated, the cleaning step may facilitate better control over the surface properties and improves the uniformity and adhesion of subsequently deposited materials. The cleaning may help to remove or reduce any metal oxide present at the bottom of the pattern. By removing this metal oxide, the vertical resistance can be reduced. Additionally, the cleaning process facilitates a void-free fill and high adhesion structure.

FIG. 1B depicts the semiconductor device after the cleaning step and subsequent exposure to a first plasma treatment. This process is further detailed, e.g., in the flow charts of FIG. 3A-3F (steps 316, 318/370, 320). After cleaning the substrate, it is loaded into a plasma processing chamber. The first plasma treatment involves exposing the substrate, including the opening 150, to a plasma containing both nitrogen and hydrogen.

To generate this first plasma, precursors containing nitrogen and hydrogen are flowed into the plasma processing chamber. These precursors may include, but are not limited to, ammonia (NH3), which serves as a source for both nitrogen and hydrogen in one embodiment. In an embodiment, the flow rate of NH3 into the chamber may be in the range of 100 to 2000 standard cubic centimeters per minute (sccm), 500 to 1500 sccm in or more embodiments, and 1000 sccm as an example.

In some embodiments, separate sources of nitrogen (such as N2) and hydrogen (H2) may be used. In further embodiments, a mixture of ammonia, nitrogen, and hydrogen may be used. In an embodiment, the flow rate of nitrogen and hydrogen into the chamber may be in the range of 500 to 1500 sccm. In certain embodiments, N2H4 gas may be used as a source for both nitrogen and hydrogen as well as in combinations with nitrogen and/or hydrogen.

The chamber pressure during this first plasma treatment may be maintained in the range of 0.1 to 10 Torr, for example, 0.5 Torr. This relatively low pressure may help to maintain a stable plasma and ensures good penetration of the plasma species into the high-aspect-ratio opening 150. The specific pressure may be chosen to balance factors such as plasma density, mean free path of the species, and overall process uniformity.

The temperature of the substrate may be maintained between 20° C. and 400° C. during the first plasma treatment. The temperature may be selected based on factors such as the thermal budget of the device being fabricated, the specific materials present on the substrate 100, and the desired reaction rates of the plasma species with the surfaces.

In one embodiment, the plasma is then generated by powering both the top and bottom electrodes of the plasma processing chamber. The substrate is typically held over the bottom electrode during this process. Power provided to the top electrode generally controls the generation of radicals while the power to the bottom electrode attracts the ions to the wafer providing directionality. This dual-frequency approach may allow for better control of the plasma characteristics and enhance the effectiveness of the treatment.

In some embodiments, the top electrode is powered with a first radio frequency (RF) waveform, while the bottom electrode is powered with a second RF waveform having a different frequency than the first RF waveform. The frequency of the first RF waveform may be 2 to 5 times the frequency of the second RF waveform in various embodiments. For example, the first RF waveform applied to the top electrode may have a frequency of 60 MHz, while the second RF waveform applied to the bottom electrode may have a frequency of 12.88 MHz. The first RF waveform may be applied to the top electrode with a power in the range of 10 to 100 Watts, and the second RF waveform may be applied to the bottom electrode with a power in the range of 100 to 1000 Watts. In one embodiment, the first RF waveform may be applied to the top electrode with a power of 50 Watts, and the second RF waveform may be applied to the bottom electrode with a power of 200 Watts. In various embodiments, this power may be applied to the top and bottom electrodes for a time duration in the range of 5 to 120 seconds.

The first plasma treatment results in the adsorption of nitrogen-hydrogen (NH) species onto the surfaces of the opening 150, including the sidewalls and the bottom surface. This adsorption process modifies the surface properties of the opening 150, enhancing the subsequent metal deposition process by improving adhesion and promoting uniform growth. The NH species form a thin layer on the surfaces, e.g., by replacing the oxygen bonds, preparing them for the next stage of the process.

The parameters of this plasma treatment, such as the gas flow rates, chamber pressure, RF power levels, and treatment duration are selected to obtain good coverage of the NH bonds across the surface of the opening 150 especially towards the bottom of the opening 150 particularly considering its high aspect ratio.

In one embodiment, the ammonia plasma may be generated by flowing ammonia at 1000 sccm with the chamber held at 0.5 Torr, by applying 50 W to the top electrode, and 200 W to the bottom electrode.

After the first plasma treatment, the plasma processing chamber may be purged to remove any residual gases before proceeding to the next step in the process. This purging step helps to ensure that the subsequent treatments or depositions are not influenced by any leftover species from the first plasma treatment.

FIG. 1C illustrates the semiconductor device after exposure to a second plasma treatment. This second plasma treatment may be performed in the same plasma processing chamber as the first treatment, but under different conditions.

This second plasma treatment prepares the surfaces of the opening 150 for subsequent metal deposition. As also illustrated in the flow chart of FIGS. 3A-3F (steps 324/360/380, 326/340/350/380), this step involves exposing the substrate to a second plasma in the same plasma processing chamber. Unlike the first plasma, this second plasma is hydrogen-free so there are no hydrogen-containing gas used to form the second plasma. In other words, the gases flowing into the plasma processing chamber at this stage, do not include hydrogen. In addition, because of the prior purge, no hydrogen remains in the plasma processing chamber.

In various embodiments, precursors containing nitrogen but no hydrogen may be flowed into the plasma processing chamber. In an embodiment, pure nitrogen (N2) may be used as the primary precursor. In the absence of hydrogen, nitrogen radicals have a relatively short lifetime and may recombine to form molecular nitrogen, and hence may not reach into the depths of the opening 150.

The flow rate of N2 into the chamber may be in the range of 100 to 1000 sccm, for example, 300 sccm in one embodiment. In one or more embodiments, the plasma may contain pure argon (Ar). In one or more embodiments, the plasma may contain both argon (Ar) and nitrogen. When Ar is used, its flow rate may be in the range of 50 to 500 sccm. In various embodiments, the ratio of N2 to Ar may be between 10:1 to 1:10, and may be adjusted to influence the plasma characteristics and the surface modification effect.

The chamber pressure during this second plasma treatment may be maintained in a range of 0.1 to 10 mTorr, for example, 0.5 Torr in on embodiment. In one or more embodiments, this pressure range may be lower than that used in the first plasma treatment, which may enhance the directionality of the plasma and promote the selective removal of hydrogen from the upper portions of the opening 150.

In various embodiments, the temperature of the substrate may be between 20° C. and 300° C. during the second plasma treatment. In one or more embodiments, the temperature may be lower than that used in the first plasma treatment to reduce thermal effects that could affect the NH species at the bottom of the opening 150. The exact temperature may be chosen based on factors such as the thermal budget of the device being fabricated and the desired selectivity of the hydrogen removal process. In various embodiments, the second plasma treatment may be performed for a shorter duration and at a lower temperature compared to the first plasma treatment. The first plasma treatment may be used to convert the entire surface of the sample into NH species. However, for the second plasma treatment, it may be sufficient to remove hydrogen from only a portion of the NH species. By reducing the plasma irradiation time or lowering the temperature of the second plasma treatment, damage to the sample can be minimized.

The plasma is then generated by powering the electrodes of the plasma processing chamber. In some embodiments, the top electrode is powered with a first radio frequency (RF) waveform, while the bottom electrode is powered with a second RF waveform having a different frequency than the first RF waveform. The frequency of the first RF waveform may be 2 to 5 times the frequency of the second RF waveform in various embodiments. For example, in one embodiment, the first RF waveform applied to the top electrode may have a frequency of 60 MHz, while the second RF waveform applied to the bottom electrode may have a frequency of 12.88 MHz. The first RF waveform may be applied to the top electrode with a power in the range of 10 to 100 Watts, and the second RF waveform may be applied to the bottom electrode with a power in the range of 100 to 1000 Watts. In one embodiment, the first RF waveform may be applied to the top electrode with a power of 50 Watts, and the second RF waveform may be applied to the bottom electrode with a power of 200 Watts.

In one or more embodiments, the power applied to the top and bottom electrodes may be lower than that used in the first plasma treatment. For example, the power applied during the second plasma treatment may be 20% to 80% of the power applied during the first plasma treatment. This lower power may help to ensure that the plasma treatment affects primarily the upper portions of the opening 150 without significantly altering the surface properties at the bottom of the opening.

In some embodiments, instead of powering both top and bottom electrodes, only the top electrode of the plasma processing chamber is powered to reduce the directionality while generating sufficient radicals. For example, the first RF waveform applied to the top electrode may have a frequency of 60 MHz. The first RF waveform may be applied to the top electrode with a power in the range of 10 to 100 Watts, for example, 50 W.

The bottom electrode may be deliberately left unpowered to avoid generating directional ions that could penetrate deep into the opening 150. If the bottom electrode were powered, it may create a potential difference that would accelerate ions towards the substrate surface. These energetic, directional ions could then travel to the bottom of the opening 150 and potentially knock off hydrogen atoms from the NH species that were deposited there during the first plasma treatment.

Accordingly, in various embodiments, by powering only the top electrode, the plasma generated is less directional and more diffusive in nature. This allows the plasma to affect primarily the upper portions of the opening 150, selectively removing hydrogen atoms from these areas. Meanwhile, the lower portions of the sidewalls and the bottom of the opening 150 are largely protected from this effect, allowing them to retain more of the NH species from the first plasma treatment.

In various embodiments, the selective removal of hydrogen creates a gradient in surface properties along the depth of the opening 150. The upper portions of the sidewalls, now covered primarily with nitrogen atoms, exhibit different chemical properties compared to the lower portions that still retain the NH species.

In one or more embodiments, the duration of this second plasma treatment may be shorter than the first treatment, and in various embodiments, may range from 3 to 60 seconds. In various embodiments, the duration of the second plasma treatment is about 10% to 80% of the duration of the first plasma treatment.

In one embodiment, the nitrogen plasma may be generated by flowing nitrogen at 300 sccm with the chamber held at 0.5 Torr, by applying 50 W to the top electrode, and 200 W to the bottom electrode.

In an embodiment, after the second plasma treatment, the chamber may be purged with an inert gas such as Ar to remove any residual reactive species before the wafer is transferred to the ruthenium deposition chamber.

After the completion of the second plasma treatment described in FIG. 1C, the substrate may be moved from the plasma processing chamber to a dedicated metal deposition chamber. This transfer is performed with utmost care to preserve the carefully prepared surface conditions within the opening 150.

The substrate transfer may be carried out using an automated handling system within the semiconductor fabrication tool without breaking vacuum. This system is designed to move wafers between different process chambers while maintaining a controlled environment. By maintaining vacuum conditions during the transfer, the risk of contamination or unwanted reactions on the treated surfaces is minimized. The vacuum transfer may be achieved through the use of load-lock chambers and transfer chambers that connect the plasma processing chamber with the ruthenium deposition chamber. These intermediate chambers may be kept under vacuum or an inert gas atmosphere to prevent exposure of the wafer to ambient air. This vacuum-to-vacuum transfer preserves the surface chemistry created by the previous plasma treatments, particularly the gradient of NH species and N atoms along the depth of the opening 150.

FIGS. 1D and 1E illustrate the gradual filling of the opening 150 with a conductive fill layer 160. FIG. 1D illustrates the conductive fill layer 160 during an intervening time during the deposition while FIG. 1E illustrates the conductive fill layer 160 after overfilling the opening 150.

Once the wafer is safely transferred to the ruthenium deposition chamber, the actual deposition process begins. The process begins with the introduction of a volatile ruthenium precursor into the deposition chamber. In the Ruthenium CVD process in accordance with embodiments, the deposition occurs through the thermal decomposition of a ruthenium-containing precursor gas on the surface of the substrate.

In various embodiments, ruthenium precursors may include organometallic compounds such as bis(ethylcyclopentadienyl)ruthenium (Ru(EtCp)2), tris(2,2,6,6-tetramethyl-3,5-heptanedionato)ruthenium (Ru(tmhd)3), or ruthenium carbonyl (Ru3(CO)12). This precursor gas is carried to the substrate surface by an inert carrier gas, typically argon or nitrogen.

In one or more embodiments, ruthenium is deposited using a thermal CVD process that utilizes a ruthenium carbonyl precursor, for example, triruthenium dodecacarbonyl (Ru3(CO)12). The ruthenium carbonyl precursor, Ru3(CO)12, is a solid at room temperature. In various embodiments, it may be heated in a precursor container to a temperature in the range of 60° C. to 100° C. to generate sufficient vapor pressure. The vaporized precursor is then carried into the deposition chamber using an inert carrier gas, which may be argon or nitrogen. The flow rate of the carrier gas may be controlled to achieve the desired precursor partial pressure in the chamber. In one or more embodiments, Ru3(CO)12 is delivered to the deposition chamber along with a carrier gas comprising carbonyl (CO) gas, where the CO gas is flown to be in contact with the solid precursor. This may reduce premature decomposition of the precursor container.

When the vaporized Ru3(CO)12 molecules come into contact with the heated surface, they undergo thermal decomposition. The deposition chamber may be maintained at a temperature in the range of 150° C. to 400° C. The chamber pressure may be regulated in the range of 1 to 50 mTorr to ensure predetermined precursor decomposition and film growth rates. Throughout the process, the gaseous byproducts of the reaction are continuously removed from the chamber by the flow of carrier gas and the chamber's vacuum system.

In one embodiment, the ruthenium deposition is performed at about 150-160° C. at 15-20 mTorr.

In various embodiments, the thermal CVD process may be performed without additional reactant gases. However, in some embodiments, a small amount of oxygen (O2) (<2%) may be introduced into the chamber to help remove carbon impurities from the growing film. The oxygen flow, if used, is carefully controlled to avoid oxidation of the ruthenium film.

As more ruthenium atoms are deposited, they nucleate and grow into a continuous film as illustrated in FIG. 1D.

The growth begins preferentially at the bottom and lower sidewalls of the opening 150, where the NH species from the first plasma treatment provide favorable nucleation sites. In contrast, the upper portions of the sidewalls, now predominantly covered with nitrogen atoms as a result of the second plasma treatment, exhibit reduced ruthenium nucleation. In addition, the surface roughness of the growing film of conductive fill layer 160 is also much better.

The CVD process parameters, including precursor flow rate, co-reactant flow rate, temperature, pressure, and deposition time, are selected to ensure a void-free fill of the opening 150. In some embodiments, the process may involve multiple cycles or stages to achieve complete filling, especially for very high aspect ratio features.

In this chamber, ruthenium atoms are deposited within the opening 150 to form the conductive fill layer 160. The deposition preferentially occurs on the bottom surface and lower portions of the sidewalls where NH species remain from the first plasma treatment. The upper portions of the sidewalls, now predominantly covered with nitrogen atoms as a result of the second plasma treatment, exhibit reduced ruthenium nucleation. The ruthenium atoms continue to accumulate, gradually filling the opening from the bottom up. This preferential deposition pattern promotes bottom-up filling of the opening 150, which is advantageous for achieving void-free metal structures in high-aspect-ratio features. Such void-free metal structures may be free of voids as well as other defects such as seams and keyholes in the deposited Ru film].

FIG. 1E illustrates the completion of the ruthenium deposition process. The opening 150 is now completely filled with ruthenium, forming a solid, void-free conductive structure comprising the conductive fill layer 160 within the first insulating layer 110. The ruthenium fill extends slightly above the top of the opening, creating a small overfill that will be addressed in subsequent processing steps.

In some embodiments, the ruthenium deposition may also be carried out using various techniques such as plasma enhanced chemical vapor deposition (CVD), or atomic layer deposition (ALD).

FIG. 1F illustrates the substrate after the metal deposition process after performing a planarization process. The planarization process, which may involve chemical mechanical polishing (CMP), ensures a flat top surface of the conductive structure, level with the surrounding first insulating layer 110. Subsequent processing may be performed as is standard semiconductor manufacturing for forming the metallization levels.

Advantageously, the process described through FIGS. 1A to 1F enables the formation of high-quality metal features in challenging geometries, contributing to the overall performance and reliability of advanced integrated circuits.

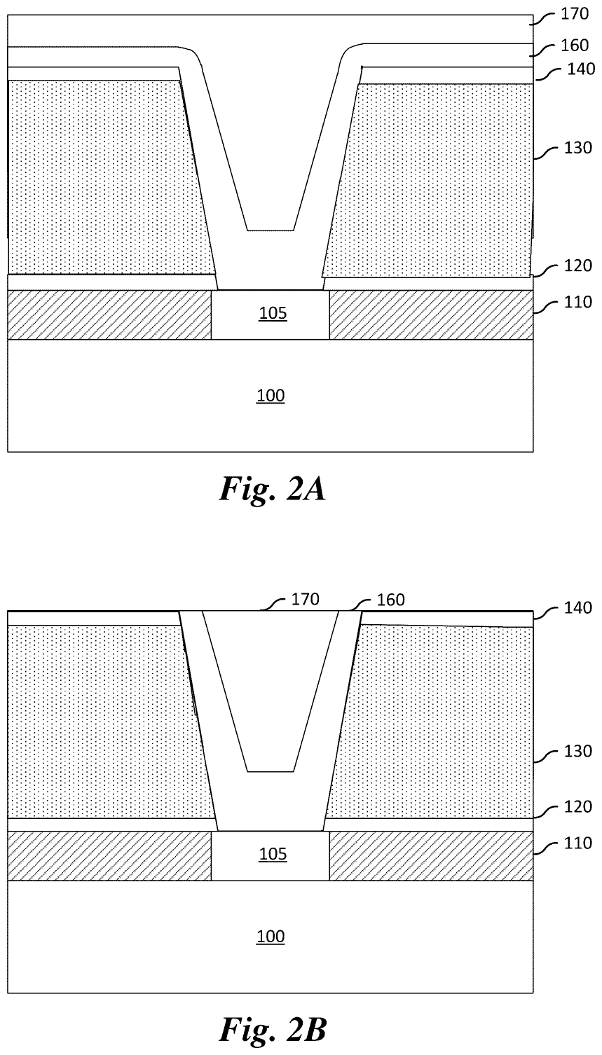

FIGS. 2A-2B illustrate cross-sectional views of a semiconductor device during various stages of fabrication in accordance with an embodiment, wherein FIG. 2A illustrates the device after the conductive fill process, and FIG. 2B illustrates the device after the planarization.

In contrast to FIGS. 1A-1F, in this embodiment, the fill process uses two different metals. Accordingly, the process flow is similar to what has been described with respect to FIGS. 1A-1D. Instead of filling with the same metal as shown in FIG. 1E, in this embodiment a different metal is used as fill layer. For example, after depositing a layer of ruthenium, the fill metal may be deposited.

In FIG. 2A, the semiconductor device is shown at a stage following the deposition of conductive materials within the opening 150. The structure includes the substrate 100, the first insulating layer 110, and the opening 150 in the second insulating layer 130, which have been previously described in relation to FIGS. 1A-1F.

As discussed above, in this embodiment, the fill process utilizes two different metals, resulting in a dual-layer conductive structure within the opening 150. The conductive fill layer 160 lines the sidewalls and bottom of the opening 150. In various embodiments, conductive fill layer 160 may be composed of ruthenium. The conductive fill layer 160 may be deposited using the plasma treatment and deposition processes described earlier in relation to FIGS. 1A-1D.

Overlying the conductive fill layer 160 is an upper conductive fill layer 170, which fills the remainder of the opening 150. In one or more embodiments, this upper conductive fill layer 170 may be composed of a different metal than the conductive fill layer 160. For example, the upper conductive fill layer 170 may be aluminum, copper, tungsten, nickel, cobalt, molybdenum, tantalum, titanium, or another suitable conductive material including nitrides such as titanium nitride, tungsten nitride, and tantalum nitride.

The deposition of the upper conductive fill layer 170 may be carried out using various techniques such as chemical vapor deposition (CVD), physical vapor deposition (PVD), electroplating, or a combination of these methods.

In various embodiments, the conductive fill layer 160 may serve as a seed layer or adhesion layer for the upper conductive fill layer 170. The dual-layer structure may combine the beneficial properties of both materials. For instance, the ruthenium layer may provide excellent adhesion to the dielectric and act as a barrier against metal diffusion, while the second metal may offer superior bulk conductivity.

As illustrated in FIG. 2A, the deposition process results in an overfill of the opening 150, with the upper conductive fill layer 170 extending above the top surface of the second etch stop liner 140. This overfill ensures complete filling of the high-aspect-ratio opening 150, preventing the formation of voids or seams within the conductive structure.

In various embodiments, the thickness of the conductive fill layer 160 may be in the range of 2 nm to 40 nm, while the thickness of the upper conductive fill layer 170 may vary depending on the dimensions of the opening 150. The relative thicknesses of these layers may be optimized to balance factors such as overall conductivity, barrier properties, and fill characteristics.

FIG. 2B illustrates the semiconductor device after a planarization process has been performed. The planarization process removes the excess material of the conductive fill layer 160 and the upper conductive fill layer 170 that extended above the top surface of the second insulating layer 130 and the second etch stop liner 140. In various embodiments, this planarization may be achieved through chemical mechanical polishing (CMP).

The CMP process may be tailored to selectively remove the overfill material while stopping on or slightly recessing the top surface of the second etch stop liner 140. The resulting structure features a substantially planar top surface, with the dual-layer conductive structure (comprising layers 160 and 170) being coplanar with the surrounding second insulating layer 130.

In one or more embodiments, the planarization process may also remove a portion of the conductive fill layer 160 that initially extended onto the top surface of the second insulating layer 130. This ensures electrical isolation of the conductive structure within the opening 150 from adjacent structures.

The planarized surface provides an ideal foundation for subsequent processing steps, such as the deposition of additional metallization layers or the formation of contacts to upper metal levels. The dual-layer conductive structure within the opening 150 may function as a via, a metal line, or both, depending on the specific design of the semiconductor device.

The dual-layer approach illustrated in FIGS. 2A and 2B may offer several advantages in certain applications. It may allow for the combination of desirable properties from different materials, such as the excellent adhesion and barrier properties of ruthenium with the high conductivity of copper. This approach may also provide flexibility in managing issues such as electromigration and stress migration in advanced semiconductor devices.

FIGS. 3A-3F illustrate flow charts depicting a method for depositing a conductive material, such as ruthenium, in an opening of a semiconductor device. This method may be used to create structures similar to those described using FIGS. 1A-1F, 2A-2B, 4.

FIG. 3A is one embodiment of a flow chart for forming a contact via, contact, metal line in accordance with embodiments. Referring first to FIG. 3A, the process begins with forming an opening for a metal line or via (step 310). This step corresponds to the formation of the opening 150 as shown in FIG. 1A. The opening may be formed in the second insulating layer 130, which is disposed over the substrate 100. In various embodiments, the opening may be a contact hole exposing the underlying conductive region 105, a trench for a metal line, or a dual damascene structure combining both a via and a trench.

Following the formation of the opening, the substrate is cleaned (step 312). This cleaning step, as described earlier, may remove any residues or contaminants left from the etching process used to form the opening. The cleaning process may also modify the surface chemistry of the exposed surfaces within the opening, potentially replacing Si—H bonds with Si—O bonds, which may facilitate subsequent processing steps.

After cleaning, the substrate is loaded into a plasma processing chamber (step 314). This may be capacitive coupled plasma (CCP) chamber in one embodiments. In other embodiments, plasma processing chamber may be an inductively coupled plasma chambers, helical resonators, and so on. This chamber may be equipped with multiple electrodes, including a top electrode and a bottom electrode, as described in the discussion of FIGS. 1B and 1C.

A flow of precursors (step 316) is initiated into the plasma processing chamber. This step corresponds to the process illustrated in FIG. 1B. In this step, precursors containing nitrogen and hydrogen are flowed into the plasma processing chamber. These precursors may include ammonia (NH3) or separate sources of nitrogen (N2) and hydrogen (H2).

The first plasma is then generated by powering both the top and bottom electrodes of the plasma processing chamber (step 318) and the substrate 100 with the opening 150 is exposed to the first plasma (step 320). As described earlier, the top electrode may be powered with a first radio frequency (RF) waveform, while the bottom electrode may be powered with a second RF waveform having a different frequency. This dual-frequency approach may allow for better control of the plasma characteristics and enhance the effectiveness of the treatment.

Following the first plasma treatment, the plasma processing chamber is purged (step 322). This purging step removes any residual gases before proceeding to the next stage of the process, ensuring that subsequent treatments are not influenced by leftover species from the first plasma treatment.

After purging, precursors containing nitrogen but no hydrogen are flowed into the plasma processing chamber (step 324). This step prepares for the second plasma treatment, which corresponds to the process illustrated in FIG. 1C. The precursors may include pure nitrogen (N2), pure argon (Ar), or a mixture of nitrogen and argon.

A second plasma is then generated by powering only the top electrode of the plasma processing chamber (step 326). This approach differs from the first plasma treatment and is designed to affect primarily the upper portions of the opening, selectively removing hydrogen atoms from these areas while largely preserving the NH species at the bottom of the opening.

Finally, ruthenium is deposited within the opening (step 328). This deposition step corresponds to the processes described using FIGS. 1D and 1E, where ruthenium atoms gradually fill the opening from the bottom up to form the conductive fill layer 160. The deposition may occur preferentially on the bottom surface and lower portions of the sidewalls where NH species remain from the first plasma treatment, promoting a bottom-up fill that is advantageous for achieving void-free metal structures in high-aspect-ratio features.

In various embodiments, this process flow may be modified to accommodate the dual-layer structure shown in FIGS. 2A and 2B. For instance, as described using FIG. 2A, after the ruthenium deposition, an additional step may be included to deposit a second conductive material to form the upper conductive fill layer 170.

The method outlined in FIG. 3A may be followed by additional steps not shown in the flow chart, such as the planarization process illustrated in FIGS. 1F and 2B. This planarization may involve chemical mechanical polishing (CMP) to ensure a flat top surface of the conductive structure, level with the surrounding first insulating layer 110.

FIG. 3B illustrates another flow chart depicting a method for depositing a conductive material, such as ruthenium, in an opening of a semiconductor device. This method shares many similarities with the process outlined in FIG. 3A, but with some differences in the second plasma treatment step.

The initial steps of the process, including forming the opening for a metal line or via (step 310), cleaning the substrate (step 312), loading the substrate into a plasma processing chamber (step 314), flowing precursors containing nitrogen and hydrogen (step 316), generating the first plasma (step 318), exposing the substrate to a first plasma (step 320), purging the plasma processing chamber (step 322), and flowing precursors containing nitrogen but no hydrogen (step 324), are similar to those described in FIG. 3A.

The difference in this process flow is represented by step 340. In this step, the second plasma is generated by powering only the top electrode of the plasma processing chamber. In other words, the bottom electrode is not powered so as to reduce directional ions coming into the opening 150 as previously described with respect to FIG. 1C.

The rest of the flow is similar to that described in FIG. 3A including depositing ruthenium within the opening (step 328), potentially including additional steps such as depositing a second conductive material (if a dual-layer structure is desired) and performing a planarization process.

FIG. 3C illustrates a third variation of the flow chart depicting a method for depositing a conductive material, such as ruthenium, in an opening of a semiconductor device. This method shares many similarities with the processes outlined in FIGS. 3A and 3B, but introduces some differences in the second plasma treatment step.

The initial steps of the process, including forming the opening for a metal line or via (step 310), cleaning the substrate (step 312), loading the substrate into a plasma processing chamber (step 314), flowing precursors containing nitrogen and hydrogen (step 316), generating the first plasma (step 318), exposing the substrate to a first plasma (step 320), purging the plasma processing chamber (step 322), and flowing precursors containing nitrogen but no hydrogen (step 324), are similar to those described in FIGS. 3A and 3B.

The difference in this process flow is represented by step 350. In this step, the second plasma is generated by powering the plasma processing chamber at low power. This approach differs from both the dual-electrode powering in FIG. 3A and the top-electrode-only powering in FIG. 3B.

In various embodiments, “low power” may refer to a power level that is significantly lower than that used in the first plasma treatment. The specific power level may be determined based on factors such as the chamber geometry, the precursor gases used, and the desired effect on the surface chemistry within the opening. In this embodiment, the low power may be applied to both top electrodes.

As also described with respect to FIG. 1C, this low-power plasma generation may result in a more gentle treatment of the surfaces within the opening. In some embodiments, this approach may help preserve more of the NH species at the bottom and lower sidewalls of the opening while still modifying the upper portions of the sidewalls.

The rest of the flow is similar to that described in FIGS. 3A and 3B including depositing of the ruthenium within the opening (step 328), potentially including additional steps such as depositing a second conductive material (if a dual-layer structure is desired) and performing a planarization process.

FIG. 3D illustrates a fourth variation of the flow chart depicting a method for depositing a conductive material, such as ruthenium, in an opening of a semiconductor device. This method shares several similarities with the processes outlined in FIGS. 3A, 3B, and 3C, with some differences in the second plasma treatment step.

The initial steps of the process, including forming the opening for a metal line or via (step 310), cleaning the substrate (step 312), loading the substrate into a plasma processing chamber (step 314), flowing precursors containing nitrogen and hydrogen (step 316), generating the first plasma (step 318), exposing the substrate to a first plasma (step 320), purging the plasma processing chamber (step 322), and flowing precursors containing nitrogen but no hydrogen (step 324), remain similar to those described in FIGS. 3A, 3B, and 3C.

The process begins to diverge at step 360. In this step, instead of nitrogen, argon is flowed into the plasma processing chamber. This marks a departure from the previous variations where nitrogen was used for the second plasma treatment. The use of argon, an inert gas, may lead to different surface modification effects compared to the nitrogen-based treatments in the previous variations.

The second difference in this process flow is represented by step 340, which is similar to the step in FIG. 3B. In this step, the second plasma is generated by powering only the top electrode of the plasma processing chamber. This approach differs from the dual-electrode powering in FIG. 3A and the low-power approach in FIG. 3C.

The combination of using argon helps to sputter the surface of NH bonds and powering only the top electrode may result in a gentle surface treatment within the opening. In various embodiments, this approach may lead to a more physical sputtering effect rather than the seen with nitrogen-based plasmas. This physical sputtering may selectively remove material from the upper portions of the opening while leaving the lower portions relatively unchanged.

The rest of the flow is similar to that described in the previous figures including step 328 and further processing.

FIG. 3E illustrates a variation of the flow chart depicting a method for depositing a conductive material, such as ruthenium, in an opening of a semiconductor device. This method shares some similarities with the processes outlined in FIGS. 3A through 3D, but introduces differences in both the first and second plasma treatment steps.

The initial steps of the process, including forming the opening for a metal line or via (step 310), cleaning the substrate (step 312), and loading the substrate into a plasma processing chamber (step 314), flowing precursors (step 316), remain similar to those described in the previous figures.

Unlike prior embodiments, in step 370, the first plasma is generated by powering only the top electrode or the bottom electrode of the plasma processing chamber. This differs from the previous variations where both electrodes were powered during the first plasma treatment. This embodiment may be used to minimize complexity in the process and hardware as the power can be applied to one electrode while grounding the other electrode.

The process then follows the familiar steps of exposing to the first plasma (step 320), purging the plasma processing chamber (step 322) and flowing precursors for the second plasma treatment (step 360). As in FIG. 3D, the precursors for the second treatment contain argon but no hydrogen, which is a departure from the nitrogen-based precursors used in FIGS. 3A through 3C.

The further difference in this process flow is represented by step 340, which is similar to the steps in FIGS. 3B and 3D. In this step, the second plasma is generated by powering only the top electrode of the plasma processing chamber and minimize directionality of the ions.

The final step of depositing ruthenium within the opening (step 328) remains the same as in the previous figures.

The rest of the flow is similar to that described in the previous figures including depositing of the ruthenium within the opening (step 328), and further processing.

The single-electrode first plasma treatment may simplify control of the plasma, potentially enhancing the treatment of the bottom of high-aspect-ratio openings. The subsequent argon-based treatment may then provide effective surface energy modification or cleaning without introducing additional chemical species.

FIG. 3F illustrates a variation of the flow chart depicting a method for depositing a conductive material, such as ruthenium, in an opening of a semiconductor device. This method shares some similarities with the processes outlined in FIGS. 3A through 3E, but introduces a difference in the second plasma treatment step.

The initial steps of the process, including forming the opening for a metal line or via (step 310), cleaning the substrate (step 312), loading the substrate into a plasma processing chamber (step 314), flowing precursors containing nitrogen and hydrogen (step 316), generating the first plasma (step 318), exposing the substrate to a first plasma (step 320), purging the plasma processing chamber (step 322), remain similar to those described in FIGS. 3A through 3C.

At step 380, precursors containing both argon and nitrogen, but no hydrogen, are flowed into the plasma processing chamber. This marks a departure from the previous variations where either nitrogen-containing precursors (FIGS. 3A-3C) or argon (FIGS. 3D-3E) were used for the second plasma treatment. The combination of argon and nitrogen may lead to a unique surface modification effect, potentially combining the benefits of both gases.

The second aspect of this process flow is represented by step 340, which is similar to the steps in FIGS. 3B, 3D, and 3E. In this step, the second plasma is generated by powering only the top electrode of the plasma processing chamber so as to minimize directional ions.

The combination of using both argon and nitrogen as precursors and powering only the top electrode may provide a balance between the chemical modification effects of nitrogen and the physical sputtering effects of argon. This dual-action treatment may be particularly effective in preparing the surface for subsequent ruthenium deposition.

The final step of depositing ruthenium within the opening (step 328) remains the same as in the previous figures and subsequent processing may also be similar.

The combination of argon and nitrogen in the second plasma treatment may allow for simultaneous surface cleaning and chemical modification. This could potentially improve both the adhesion of the ruthenium layer and its nucleation characteristics, leading to more uniform and void-free filling of high-aspect-ratio openings.

The methods described above in various embodiments enable the formation of high-quality metal features in challenging geometries, contributing to the overall performance and reliability of advanced integrated circuits. The careful sequencing of plasma treatments and deposition steps may allow for precise control over the fill process, potentially reducing defects and improving the electrical characteristics of the resulting structures.

Although the above embodiments have been described as being performed at the front side of the devices, embodiments may also be used to deposit metal such as ruthenium at the back side of the substrate, e.g., as part of a redistribution layer. Similarly, embodiments, may be applied to metallization processes during wafer level packaging processes in some embodiments.

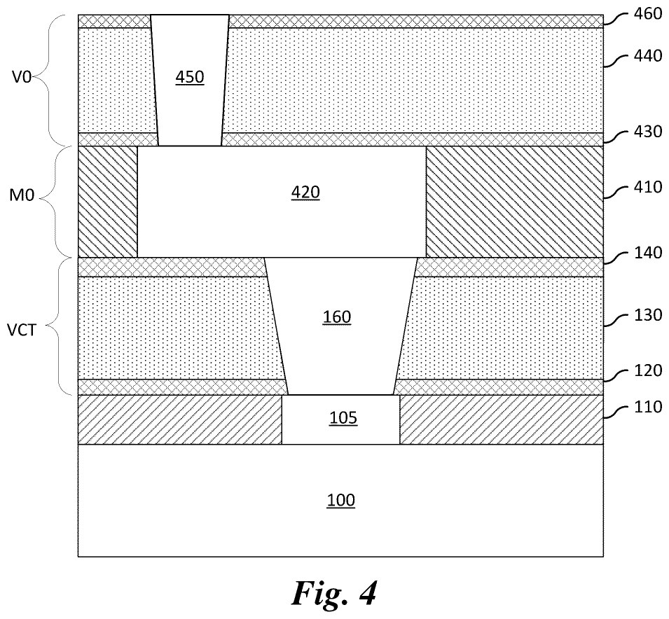

FIG. 4 illustrates a cross-sectional view of a semiconductor device formed using embodiments described above.

For example, FIG. 4 illustrates a via contact (VCT) formed at a lower level above the substrate, a first metal level (MO) formed above the VCT layer, and a first via level (V0) formed above the first metal level.

Besides, the conductive fill layer 160 described in prior embodiments, as being formed using the processes described in FIGS. 3A-3F (as well as FIGS. 1A-1F, 2A-2B), the first metal line 420, the first via 450 may also be formed using a similar process described using the flow charts of FIGS. 3A-3F.

Referring to FIG. 4, the semiconductor device is built upon a substrate 100, which may be a semiconductor material such as silicon, silicon-on-insulator (SOI), or a compound semiconductor. On top of the substrate 100, a first insulating layer 110 is deposited.

Within the first insulating layer 110, a conductive region 105 is formed. This conductive region may represent a source contact region, drain contact region, or gate contact region of a transistor, or another type of conductive structure at the substrate level. Above the first insulating layer 110, a first etch stop liner 120 is deposited. This liner may serve as an etch stop during the formation of vias and may also act as a diffusion barrier.

A second insulating layer 130 is deposited over the first etch stop liner 120. This layer may be composed of a low-k dielectric material to reduce parasitic capacitance in the device. This layer, along with a second etch stop liner 140 above it, forms the dielectric stack in which the via contact (VCT) is created. The VCT is represented by the conductive fill layer 160, which may be formed using the processes described in FIGS. 3A-3F (as well as FIGS. 1A-1F, 2A-2B). This via contact provides electrical connection between the conductive region 105 and the upper metal levels.

Moving up the stack, a third insulating layer 410 is deposited above the second etch stop liner 140 and patterned to form a trench for a metal line. Within this trench, the first metal line 420 comprising ruthenium may be formed as per the embodiments described in FIGS. 3A-3F (as well as FIGS. 1A-1F, 2A-2B). This metal line represents the first metal level (M0) of the interconnect structure.

A third etch stop liner 430 is then deposited over the third insulating layer 410 and the first metal line 420. Above the third etch stop liner 430, a fourth insulating layer 440 is deposited. This layer hosts the first via 450, which provides a vertical connection between the first metal line 420 and the next metal level (not shown in this figure). Formation of the first via 450 may follow a process similar to the via contact formation in which an opening is formed within the fourth etch stop liner 460, the fourth insulating layer 440, and third etch stop liner 430. The opening for the via may be filled with ruthenium using a process described in FIGS. 3A-3F (as well as FIGS. 1A-1F, 2A-2B).

As discussed above, not only the conductive fill layer 160 (forming the VCT), but also the first metal line 420 and the first via 450 may be formed using processes similar to those described in the flow charts of FIGS. 3A-3F (as well as FIGS. 1A-1F, 2A-2B). Of course, higher metallization levels may also incorporate similar methods.

In a different embodiment, the methods described in FIGS. 3A-3F may be performed in a dual damascene process where ruthenium may be filled simultaneously into a via opening and metal line.

The use of these advanced deposition techniques for multiple conductive structures (VCT, M0, V0) may result in improved fill characteristics, particularly for high-aspect-ratio features. This can lead to better overall performance of the integrated circuit, with potentially lower resistance in the interconnect structure and improved reliability due to the reduction of voids or seams in the conductive features.

In various embodiments, the conductive fill layer 160, the first metal line 420, and the first via 450 may be composed of ruthenium, or they may utilize a dual-layer structure as described in relation to FIGS. 2A and 2B. The choice of materials and specific deposition parameters may be optimized for each level of the metallization stack to meet the particular requirements of resistance, electromigration resistance, and compatibility with surrounding materials.

This multi-level structure illustrates how the deposition methods described in earlier sections can be integrated into a complete metallization scheme for advanced semiconductor devices. By applying these techniques across multiple levels, manufacturers may achieve consistent and high-quality conductive structures throughout the interconnect stack, potentially leading to improved device performance and reliability.

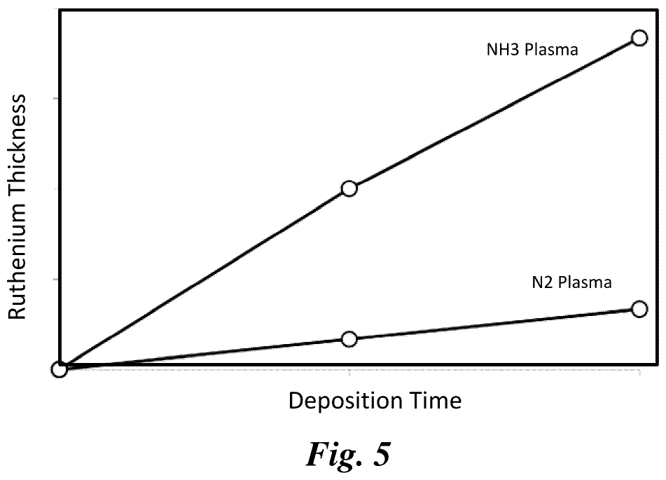

FIG. 5 illustrates representative initial growth rates of ruthenium using different plasma treatments. Prior to identifying the two-step plasma process described above, inventors of this application conducted experiments on depositing ruthenium after a single step plasma surface treatment such as ammonia and nitrogen.

As clearly shown, even in the early stages of deposition, the NH3 plasma treatment results in a significantly higher growth rate of ruthenium compared to the N2 plasma treatment. This graph demonstrates the substantial increase in initial deposition rate achieved with NH3 plasma treatment, compared to the much slower deposition rate with N2 plasma treatment. This marked difference in growth rates is utilized in the two step process to achieve a bottom up growth rate as described above in various embodiments. Applicant have conducted experiments with various two-step described above and obtained void free fills with better surface roughness.

Example embodiments of the invention are described below. Other embodiments can also be understood from the entirety of the specification as well as the claims filed herein.

Example 1. A method for depositing ruthenium includes forming an opening in a dielectric layer disposed over a substrate, exposing the substrate including the opening to a first plasma in a plasma processing chamber including nitrogen and hydrogen, and exposing the substrate including the opening to a second plasma in the plasma processing chamber. The second plasma is hydrogen free. The method includes depositing ruthenium into the opening after exposing the substrate to the second plasma.

Example 2. The method of example 1, further includes loading the substrate into the plasma processing chamber; and prior to the depositing of the ruthenium, moving the substrate to a processing chamber after exposing the substrate to the second plasma.

Example 3. The method of one of examples 1 or 2, further includes performing a purge between the exposing to the first plasma and the exposing to the second plasma.

Example 4. The method of one of examples 1 to 3, where the exposing the substrate including the opening to the first plasma includes: flowing ammonia into the plasma processing chamber; and generating the first plasma from the ammonia.

Example 5. The method of one of examples 1 to 4, where generating the first plasma includes powering a top electrode of the plasma processing chamber and powering a bottom electrode of the plasma processing chamber, the substrate being held over the bottom electrode.

Example 6. The method of one of examples 1 to 5, where the top electrode is powered with a first radio frequency (RF) waveform, and the bottom electrode is powered with a second RF waveform having a different frequency than the first RF waveform.

Example 7. The method of one of examples 1 to 6, where the first RF waveform has a frequency of 60 MHz and the second RF waveform has a frequency of 12.88 MHz.

Example 8. The method of one of examples 1 to 7, where generating the first plasma includes powering either a top electrode of the plasma processing chamber or a bottom electrode of the plasma processing chamber, the substrate being held over the bottom electrode.

Example 9. The method of one of examples 1 to 8, where the exposing the substrate to the first plasma includes: flowing nitrogen and hydrogen and/or N2H2 into the plasma processing chamber; and generating the first plasma from the nitrogen and the hydrogen.

Example 10. The method of one of examples 1 to 9, where generating the first plasma includes powering a top electrode of the plasma processing chamber and powering a bottom electrode of the plasma processing chamber, the substrate being held over the bottom electrode.

Example 11. The method of one of examples 1 to 10, where the top electrode is powered with a first radio frequency (RF) waveform, and the bottom electrode is powered with a second RF waveform having a different frequency than the first RF waveform.

Example 12. The method of one of examples 1 to 11, where the first RF waveform has a frequency of 60 MHz and the second RF waveform has a frequency of 12.88 MHz.

Example 13. The method of one of examples 1 to 12, where the dielectric layer includes a low-k dielectric, silicon di oxide, or silicon nitride.

Example 14. The method of one of examples 1 to 13, where forming the opening includes forming a contact hole to expose an underlying metal line or forming a trench for a metal line.

Example 15. The method of one of examples 1 to 14, where forming the opening includes forming a contact hole and a trench for a metal line, and where depositing the ruthenium into the opening includes simultaneously filling the contact hole and the trench for the metal line.

Example 16. The method of one of examples 1 to 15, where the depositing is performed using a thermal chemical vapor deposition process.

Example 17. A method for depositing ruthenium includes forming an opening in a dielectric layer disposed over a substrate, exposing the substrate including the opening to a first plasma in a plasma processing chamber including nitrogen and hydrogen, flowing an inert gas into the plasma processing chamber, generating a second plasma from the inert gas, and exposing the substrate including the opening to the second plasma, where the second plasma is hydrogen free. The method includes using a thermal chemical vapor deposition process, depositing ruthenium into the opening after exposing the substrate to the second plasma.

Example 18. The method of example 17, where generating the second plasma includes powering a top electrode of the plasma processing chamber without powering a bottom electrode of the plasma processing chamber, the substrate being held over the bottom electrode.

Example 19. The method of one of examples 17 or 18, where the top electrode is powered with a radio frequency (RF) waveform.

Example 20. The method of one of examples 17 to 19, where the inert gas includes nitrogen or argon.

Example 21. A method for depositing ruthenium includes forming an opening in a dielectric layer disposed over a substrate, the opening including sidewalls and a bottom surface. The method includes using a first plasma process, adsorbing nitrogen and hydrogen atoms to the bottom surface and sidewalls. The method includes using a second plasma process, selectively removing hydrogen atoms from upper portions of the sidewalls, and depositing ruthenium into the opening after the second plasma process.

Example 22. The method of example 21, where using the first plasma process includes: flowing ammonia into a plasma processing chamber; generating a first plasma from the ammonia; and exposing the substrate to the first plasma.

Example 23. The method of one of examples 21 or 22, where using the first plasma process includes: flowing nitrogen and hydrogen into a plasma processing chamber; generating a first plasma from the nitrogen and hydrogen; and exposing the substrate to the first plasma.

Example 24. The method of one of examples 21 to 23, where using the second plasma process includes: flowing a hydrogen-free inert gas into the plasma processing chamber; generating a second plasma from the inert gas; and exposing the substrate to the second plasma.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for depositing ruthenium, the method comprising:
forming an opening in a dielectric layer disposed over a substrate;
exposing the substrate comprising the opening to a first plasma in a plasma processing chamber comprising nitrogen and hydrogen;
exposing the substrate comprising the opening to a second plasma in the plasma processing chamber, the second plasma being hydrogen free; and
depositing ruthenium into the opening after exposing the substrate to the second plasma.

2. The method of claim 1, further comprising:
loading the substrate into the plasma processing chamber; and
prior to the depositing of the ruthenium, moving the substrate to a processing chamber after exposing the substrate to the second plasma.

3. The method of claim 1, further comprising performing a purge between the exposing to the first plasma and the exposing to the second plasma.

4. The method of claim 1, wherein the exposing the substrate comprising the opening to the first plasma comprises:
flowing ammonia into the plasma processing chamber; and
generating the first plasma from the ammonia.

5. The method of claim 4, wherein generating the first plasma comprises powering a top electrode of the plasma processing chamber and powering a bottom electrode of the plasma processing chamber, the substrate being held over the bottom electrode.

6. The method of claim 5, wherein the top electrode is powered with a first radio frequency (RF) waveform, and the bottom electrode is powered with a second RF waveform having a different frequency than the first RF waveform.

7. The method of claim 6, wherein the first RF waveform has a frequency of 60 MHz and the second RF waveform has a frequency of 12.88 MHz.

8. The method of claim 1, wherein the exposing the substrate to the first plasma comprises:
flowing nitrogen and hydrogen into the plasma processing chamber; and
generating the first plasma from the nitrogen and the hydrogen.

9. The method of claim 1, wherein the exposing the substrate to the first plasma comprises:
flowing N2H2 into the plasma processing chamber; and
generating the first plasma from the N2H2.

10. The method of claim 8, wherein generating the first plasma comprises powering a top electrode of the plasma processing chamber and powering a bottom electrode of the plasma processing chamber, the substrate being held over the bottom electrode.

11. The method of claim 10, wherein the top electrode is powered with a first radio frequency (RF) waveform, and the bottom electrode is powered with a second RF waveform having a different frequency than the first RF waveform.

12. The method of claim 11, wherein the first RF waveform has a frequency of 60 MHz and the second RF waveform has a frequency of 12.88 MHz.

13. The method of claim 1, wherein the depositing is performed using a thermal chemical vapor deposition process.

14. A method for depositing ruthenium, the method comprising:
forming an opening in a dielectric layer disposed over a substrate;
exposing the substrate comprising the opening to a first plasma in a plasma processing chamber comprising nitrogen and hydrogen;
flowing an inert gas into the plasma processing chamber, generating a second plasma from the inert gas, and exposing the substrate comprising the opening to the second plasma, the second plasma being hydrogen free; and
using a thermal chemical vapor deposition process, depositing ruthenium into the opening after exposing the substrate to the second plasma.

15. The method of claim 14, wherein generating the second plasma comprises powering a top electrode of the plasma processing chamber without powering a bottom electrode of the plasma processing chamber, the substrate being held over the bottom electrode.

16. The method of claim 15, wherein the top electrode is powered with a radio frequency (RF) waveform.

17. The method of claim 15, wherein the inert gas comprises nitrogen or argon.

18. A method for depositing ruthenium, the method comprising:
forming an opening in a dielectric layer disposed over a substrate, the opening comprising sidewalls and a bottom surface;
using a first plasma process, adsorbing nitrogen and hydrogen atoms to the bottom surface and sidewalls;
using a second plasma process, selectively removing hydrogen atoms from upper portions of the sidewalls; and
depositing ruthenium into the opening after the second plasma process.

19. The method of claim 18, wherein using the first plasma process comprises:
flowing ammonia into a plasma processing chamber;
generating a first plasma from the ammonia; and
exposing the substrate to the first plasma.

20. The method of claim 18, wherein using the first plasma process comprises:
flowing nitrogen and hydrogen into a plasma processing chamber;
generating a first plasma from the nitrogen and hydrogen; and
exposing the substrate to the first plasma.

21. The method of claim 18, wherein using the second plasma process comprises:
flowing a hydrogen-free inert gas into the plasma processing chamber;
generating a second plasma from the inert gas; and
exposing the substrate to the second plasma.
